(19) United States
(12) Patent Application Publication
(10) Pub. No.: US 2020/0049071 A1
(43) Pub. Date: Feb. 13, 2020

(54) APPARATUS FOR GAS TURBINE ENGINES

(71) Applicant: ROLLS-ROYCE plc, London (GB)

(72) Inventors: Edward John HEENEN, Newport (GB); Michael J. SHEATH, Derby (GB); Neil J. DAVIES, Derby (GB)

(73) Assignee: ROLLS-ROYCE plc, London (GB)

(21) Appl. No.: 16/529,126

(22) Filed: Aug. 1, 2019

(30) Foreign Application Priority Data
Aug. 13, 2018 (GB) 1813165.6

(51) Int. Cl. F02C 7/14; H01L 35/00

(52) U.S. Cl. CPC F02C 7/14; F05D 2260/213; H01L 35/00

(57) ABSTRACT

Apparatus for a gas turbine engine, the apparatus comprising: an engine core; a nacelle; and thermal energy transfer apparatus configured to transfer thermal energy from the engine core to the nacelle.

### CROSS-REFERENCE TO RELATED APPLICATIONS

This specification is based upon and claims the benefit of priority from UK Patent Application Number 1813165.6 filed on 13 Aug. 2018, the entire contents of which are incorporated herein by reference.

### TECHNOLOGICAL FIELDS

The present disclosure relates to apparatus for gas turbine engines.

### BACKGROUND

Gas turbine engines may include an engine core and a nacelle that together define a bypass duct. The engine core may be vented with air flowing in the bypass duct to cool components of the engine core and to reduce the build-up of hazardous vapours. However, at low power conditions, heat from the engine core may not be completely removed due to the relatively low air speed in the bypass duct.

### BRIEF SUMMARY

According to a first aspect there is provided apparatus for a gas turbine engine, the apparatus comprising: an engine core; a nacelle; and thermal energy transfer apparatus configured to transfer thermal energy from the engine core to the nacelle.

The thermal energy transfer apparatus may comprise: a first heat exchanger configured to transfer thermal energy to a fluid; a second heat exchanger configured to transfer thermal energy from the fluid; and a conduit arrangement configured to enable the fluid to flow between the first heat exchanger and the second heat exchanger.

The conduit arrangement may comprise: a first conduit connected between the first heat exchanger and the second heat exchanger and configured to enable the fluid to flow from the first heat exchanger to the second heat exchanger; and a second conduit connected between the first heat exchanger and the second heat exchanger, the second conduit being separate from the first conduit and configured to enable the fluid to flow from the second heat exchanger to the first heat exchanger.

The conduit arrangement may comprise a heat pipe connected between the first heat exchanger and the second heat exchanger.

The apparatus may further comprise: a casing comprising: an inner wall defining at least part of a core airflow path through the gas turbine engine; an outer wall defining an external surface of the core engine casing, a first cavity being defined between the inner wall and the outer wall of the casing, the first heat exchanger being positioned within the first cavity of the casing.

The engine core may comprise a bearing housing defining a second cavity for housing a bearing, the first heat exchanger being positioned within the second cavity of the bearing housing.

The thermal energy transfer apparatus may comprise: a thermoelectric generator configured to generate electrical energy from thermal energy produced by the engine core; and an electrical heater configured to receive electrical energy generated by the thermoelectric generator.

The apparatus may further comprise an electrical component configured to receive electrical energy generated by the thermoelectric generator.

The electrical component may comprise an electrical energy storage device configured to store electrical energy generated by the thermoelectric generator.

The apparatus may further comprise: a casing comprising: an inner wall defining at least part of a core airflow path through the gas turbine engine; an outer wall defining an external surface of the casing, a first cavity being defined between the inner wall and the outer wall of the casing, the thermoelectric generator being positioned within the first cavity of the casing.

The engine core may comprise a bearing housing defining a second cavity for housing a bearing, the thermoelectric generator being positioned within the second cavity of the bearing housing.

According to a second aspect there is provided a gas turbine engine for an aircraft, the gas turbine engine comprising apparatus as described in the preceding paragraphs.

The engine core may further comprise a turbine, a compressor, and a core shaft connecting the turbine to the compressor; a fan located upstream of the engine core, the fan comprising a plurality of fan blades; and a gearbox that receives an input from the core shaft and outputs drive to the fan so as to drive the fan at a lower rotational speed than the core shaft.

The turbine may be a first turbine, the compressor may be a first compressor, and the core shaft may be a first core shaft; the engine core may further comprise a second turbine, a second compressor, and a second core shaft connecting the second turbine to the second compressor; and the second turbine, second compressor, and second core shaft are arranged to rotate at a higher rotational speed than the first core shaft.

As noted elsewhere herein, the present disclosure may relate to a gas turbine engine. Such a gas turbine engine may comprise an engine core comprising a turbine, a combustor, a compressor, and a core shaft connecting the turbine to the compressor. Such a gas turbine engine may comprise a fan (having fan blades) located upstream of the engine core.

Arrangements of the present disclosure may be particularly, although not exclusively, beneficial for fans that are driven via a gearbox. Accordingly, the gas turbine engine may comprise a gearbox that receives an input from the core shaft and outputs drive to the fan so as to drive the fan at a lower rotational speed than the core shaft. The input to the gearbox may be directly from the core shaft, or indirectly from the core shaft, for example via a spur shaft and/or gear. The core shaft may rigidly connect the turbine and the compressor, such that the turbine and compressor rotate at the same speed (with the fan rotating at a lower speed).

The gas turbine engine as described and/or claimed herein may have any suitable general architecture. For example, the gas turbine engine may have any desired number of shafts that connect turbines and compressors, for example one, two or three shafts. Purely by way of example, the turbine connected to the core shaft may be a first turbine, the compressor connected to the core shaft may be a first compressor, and the core shaft may be a first core shaft. The engine core may further comprise a second turbine, a second compressor, and a second core shaft connecting the second turbine to the second compressor. The second turbine, second compressor, and second core shaft may be arranged to rotate at a higher rotational speed than the first core shaft.

In such an arrangement, the second compressor may be positioned axially downstream of the first compressor. The second compressor may be arranged to receive (for example directly receive, for example via a generally annular duct) flow from the first compressor.

The gearbox may be arranged to be driven by the core shaft that is configured to rotate (for example in use) at the lowest rotational speed (for example the first core shaft in the example above). For example, the gearbox may be arranged to be driven only by the core shaft that is configured to rotate (for example in use) at the lowest rotational speed (for example only be the first core shaft, and not the second core shaft, in the example above). Alternatively, the gearbox may be arranged to be driven by any one or more shafts, for example the first and/or second shafts in the example above.

In any gas turbine engine as described and/or claimed herein, a combustor may be provided axially downstream of the fan and compressor(s). For example, the combustor may be directly downstream of (for example at the exit of) the second compressor, where a second compressor is provided. By way of further example, the flow at the exit to the combustor may be provided to the inlet of the second turbine, where a second turbine is provided. The combustor may be provided upstream of the turbine(s).

The, or each compressor (for example the first compressor and second compressor as described above) may comprise any number of stages, for example multiple stages. Each stage may comprise a row of rotor blades and a row of stator vanes, which may be variable stator vanes (in that their angle of incidence may be variable). The row of rotor blades and the row of stator vanes may be axially offset from each other.

The, or each turbine (for example the first turbine and second turbine as described above) may comprise any number of stages, for example multiple stages. Each stage may comprise a row of rotor blades and a row of stator vanes. The row of rotor blades and the row of stator vanes may be axially offset from each other.

Each fan blade may be defined as having a radial span extending from a root (or hub) at a radially inner gas-washed location, or 0% span position, to a tip at a 100% span position. The ratio of the radius of the fan blade at the hub to the radius of the fan blade at the tip may be less than (or in the order of) any of: 0.4, 0.39, 0.38 0.37, 0.36, 0.35, 0.34, 0.33, 0.32, 0.31, 0.3, 0.29, 0.28, 0.27, 0.26, or 0.25. The ratio of the radius of the fan blade at the hub to the radius of the fan blade at the tip may be in an inclusive range bounded by any two of the values in the previous sentence (i.e. the values may form upper or lower bounds). These ratios may commonly be referred to as the hub-to-tip ratio. The radius at the hub and the radius at the tip may both be measured at the leading edge (or axially forward most) part of the blade. The hub-to-tip ratio refers, of course, to the gas-washed portion of the fan blade, i.e. the portion radially outside any platform.

The radius of the fan may be measured between the engine centreline and the tip of a fan blade at its leading edge. The fan diameter (which may simply be twice the radius of the fan) may be greater than (or in the order of) any of: 250 cm (around 100 inches), 260 cm, 270 cm (around 105 inches), 280 cm (around 110 inches), 290 cm (around 115 inches), 300 cm (around 120 inches), 310 cm, 320 cm (around 125 inches), 330 cm (around 130 inches), 340 cm (around 135 inches), 350 cm, 360 cm (around 140 inches), 370 cm (around 145 inches), 380 (around 150 inches) cm or 390 cm (around 155 inches). The fan diameter may be in an inclusive range bounded by any two of the values in the previous sentence (i.e. the values may form upper or lower bounds).

The rotational speed of the fan may vary in use. Generally, the rotational speed is lower for fans with a higher diameter. Purely by way of non-limitative example, the rotational speed of the fan at cruise conditions may be less than 2500 rpm, and may be, for example, less than 2300 rpm. Purely by way of further non-limitative example, the rotational speed of the fan at cruise conditions for an engine having a fan diameter in the range of from 250 cm to 300 cm (for example 250 cm to 280 cm) may be in the range of from 1700 rpm to 2500 rpm, for example in the range of from 1800 rpm to 2300 rpm, for example in the range of from 1900 rpm to 2100 rpm. Purely by way of further non-limitative example, the rotational speed of the fan at cruise conditions for an engine having a fan diameter in the range of from 320 cm to 380 cm may be in the range of from 1200 rpm to 2000 rpm, for example in the range of from 1300 rpm to 1800 rpm, for example in the range of from 1400 rpm to 1600 rpm.

In use of the gas turbine engine, the fan (with associated fan blades) rotates about a rotational axis. This rotation results in the tip of the fan blade moving with a velocity Uₜᵢₚ. The work done by the fan blades on the flow results in an enthalpy rise dH of the flow. A fan tip loading may be defined as dH/Uₜᵢₚ², where dH is the enthalpy rise (for example the 1-D average enthalpy rise) across the fan and Uₜᵢₚ is the (translational) velocity of the fan tip, for example at the leading edge of the tip (which may be defined as fan tip radius at leading edge multiplied by angular speed). The fan tip loading at cruise conditions may be greater than (or on the order of) any of: 0.3, 0.31, 0.32, 0.33, 0.34, 0.35, 0.36, 0.37, 0.38, 0.39 or 0.4 (all units in this paragraph being Jkg⁻¹K⁻¹/(ms⁻¹)²). The fan tip loading may be in an inclusive range bounded by any two of the values in the previous sentence (i.e. the values may form upper or lower bounds).

Gas turbine engines in accordance with the present disclosure may have any desired bypass ratio, where the bypass ratio is defined as the ratio of the mass flow rate of the flow through the bypass duct to the mass flow rate of the flow through the core at cruise conditions. In some arrangements the bypass ratio may be greater than (or on the order of) any of the following: 10, 10.5, 11, 11.5, 12, 12.5, 13, 13.5, 14, 14.5, 15, 15.5, 16, 16.5, or 17. The bypass ratio may be in an inclusive range bounded by any two of the values in the previous sentence (i.e. the values may form upper or lower bounds). The bypass duct may be substantially annular. The bypass duct may be radially outside the core engine. The radially outer surface of the bypass duct may be defined by a nacelle and/or a fan case.

The overall pressure ratio of a gas turbine engine as described and/or claimed herein may be defined as the ratio of the stagnation pressure upstream of the fan to the stagnation pressure at the exit of the highest pressure compressor (before entry into the combustor). By way of non-limitative example, the overall pressure ratio of a gas turbine engine as described and/or claimed herein at cruise may be greater than (or on the order of) any of the following: 35, 40, 45, 50, 55, 60, 65, 70, 75. The overall pressure ratio may be in an inclusive range bounded by any two of the values in the previous sentence (i.e. the values may form upper or lower bounds).

Specific thrust of an engine may be defined as the net thrust of the engine divided by the total mass flow through the engine. At cruise conditions, the specific thrust of an engine described and/or claimed herein may be less than (or on the order of) any of the following: 110 Nkg⁻¹s, 105 Nkg⁻¹s, 100 Nkg⁻¹s, 95 9Nkg⁻¹s, 90 Nkg⁻¹s, 85 Nkg⁻¹s or 80 Nkg⁻¹s. The specific thrust may be in an inclusive range bounded by any two of the values in the previous sentence (i.e. the values may form upper or lower bounds). Such engines may be particularly efficient in comparison with conventional gas turbine engines.

A gas turbine engine as described and/or claimed herein may have any desired maximum thrust. Purely by way of non-limitative example, a gas turbine as described and/or claimed herein may be capable of producing a maximum thrust of at least (or on the order of) any of the following: 160 kN, 170 kN, 180 kN, 190 kN, 200 kN, 250 kN, 300 kN, 350 kN, 400 kN, 450 kN, 500 kN, or 550 kN. The maximum thrust may be in an inclusive range bounded by any two of the values in the previous sentence (i.e. the values may form upper or lower bounds). The thrust referred to above may be the maximum net thrust at standard atmospheric conditions at sea level plus 15 deg C (ambient pressure 101.3 kPa, temperature 30 deg C), with the engine static.

In use, the temperature of the flow at the entry to the high pressure turbine may be particularly high. This temperature, which may be referred to as TET, may be measured at the exit to the combustor, for example immediately upstream of the first turbine vane, which itself may be referred to as a nozzle guide vane. At cruise, the TET may be at least (or on the order of) any of the following: 1400K, 1450K, 1500K, 1550K, 1600K or 1650K. The TET at cruise may be in an inclusive range bounded by any two of the values in the previous sentence (i.e. the values may form upper or lower bounds). The maximum TET in use of the engine may be, for example, at least (or in the order of) any of the following: 1700K, 1750K, 1800K, 1850K, 1900K, 1950K or 2000K. The maximum TET may be in an inclusive range bounded by any two of the values in the previous sentence (i.e. the values may form upper or lower bounds). The maximum TET may occur, for example, at a high thrust condition, for example at a maximum take-off (MTO) condition.

A fan blade and/or aerofoil portion of a fan blade described and/or claimed herein may be manufactured from any suitable material or combination of materials. For example at least a part of the fan blade and/or aerofoil may be manufactured at least in part from a composite, for example a metal matrix composite and/or an organic matrix composite, such as carbon fibre. By way of further example at least a part of the fan blade and/or aerofoil may be manufactured at least in part from a metal, such as a titanium based metal or an aluminium based material (such as an aluminium-lithium alloy) or a steel based material. The fan blade may comprise at least two regions manufactured using different materials. For example, the fan blade may have a protective leading edge, which may be manufactured using a material that is better able to resist impact (for example from birds, ice or other material) than the rest of the blade. Such a leading edge may, for example, be manufactured using titanium or a titanium-based alloy. Thus, purely by way of example, the fan blade may have a carbon-fibre or aluminium based body (such as an aluminium lithium alloy) with a titanium leading edge.

A fan as described and/or claimed herein may comprise a central portion, from which the fan blades may extend, for example in a radial direction. The fan blades may be attached to the central portion in any desired manner. For example, each fan blade may comprise a fixture which may engage a corresponding slot in the hub (or disc). Purely by way of example, such a fixture may be in the form of a dovetail that may slot into and/or engage a corresponding slot in the hub/disc in order to fix the fan blade to the hub/disc. By way of further example, the fan blades maybe formed integrally with a central portion. Such an arrangement may be referred to as a bladed disc or a bladed ring. Any suitable method may be used to manufacture such a bladed disc or bladed ring. For example, at least a part of the fan blades may be machined from a block and/or at least part of the fan blades may be attached to the hub/disc by welding, such as linear friction welding.

The gas turbine engines described and/or claimed herein may or may not be provided with a Variable Area Nozzle (VAN). Such a Variable Area Nozzle may allow the exit area of the bypass duct to be varied in use. The general principles of the present disclosure may apply to engines with or without a VAN.

The fan of a gas turbine as described and/or claimed herein may have any desired number of fan blades, for example 16, 18, 20, or 22 fan blades.

As used herein, cruise conditions may mean cruise conditions of an aircraft to which the gas turbine engine is attached. Such cruise conditions may be conventionally defined as the conditions at mid-cruise, for example the conditions experienced by the aircraft and/or engine at the midpoint (in terms of time and/or distance) between top of climb and start of decent.

Purely by way of example, the forward speed at the cruise condition may be any point in the range of from Mach 0.7 to 0.9, for example 0.75 to 0.85, for example 0.76 to 0.84, for example 0.77 to 0.83, for example 0.78 to 0.82, for example 0.79 to 0.81, for example in the order of Mach 0.8, in the order of Mach 0.85 or in the range of from 0.8 to 0.85. Any single speed within these ranges may be the cruise condition. For some aircraft, the cruise conditions may be outside these ranges, for example below Mach 0.7 or above Mach 0.9.

Purely by way of example, the cruise conditions may correspond to standard atmospheric conditions at an altitude that is in the range of from 10000 m to 15000 m, for example in the range of from 10000 m to 12000 m, for example in the range of from 10400 m to 11600 m (around 38000 ft), for example in the range of from 10500 m to 11500 m, for example in the range of from 10600 m to 11400 m, for example in the range of from 10700 m (around 35000 ft) to 11300 m, for example in the range of from 10800 m to 11200 m, for example in the range of from 10900 m to 11100 m, for example on the order of 11000 m. The cruise conditions may correspond to standard atmospheric conditions at any given altitude in these ranges.

Purely by way of example, the cruise conditions may correspond to: a forward Mach number of 0.8; a pressure of 23000 Pa; and a temperature of −55 deg C.

As used anywhere herein, “cruise” or “cruise conditions” may mean the aerodynamic design point. Such an aerodynamic design point (or ADP) may correspond to the conditions (comprising, for example, one or more of the Mach Number, environmental conditions and thrust requirement) for which the fan is designed to operate. This may mean, for example, the conditions at which the fan (or gas turbine engine) is designed to have optimum efficiency.

In use, a gas turbine engine described and/or claimed herein may operate at the cruise conditions defined elsewhere herein. Such cruise conditions may be determined by the cruise conditions (for example the mid-cruise conditions) of an aircraft to which at least one (for example 2 or 4) gas turbine engine may be mounted in order to provide propulsive thrust.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION

Embodiments will now be described by way of example only, with reference to the Figures, in which:

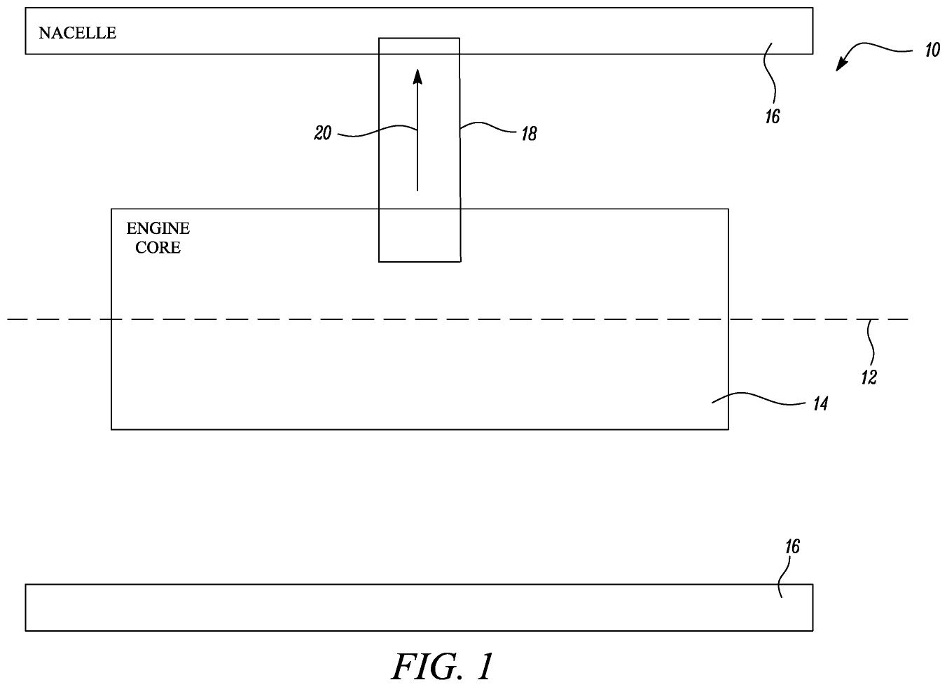

FIG. 1 illustrates a schematic diagram of apparatus for a gas turbine engine according to a first example;

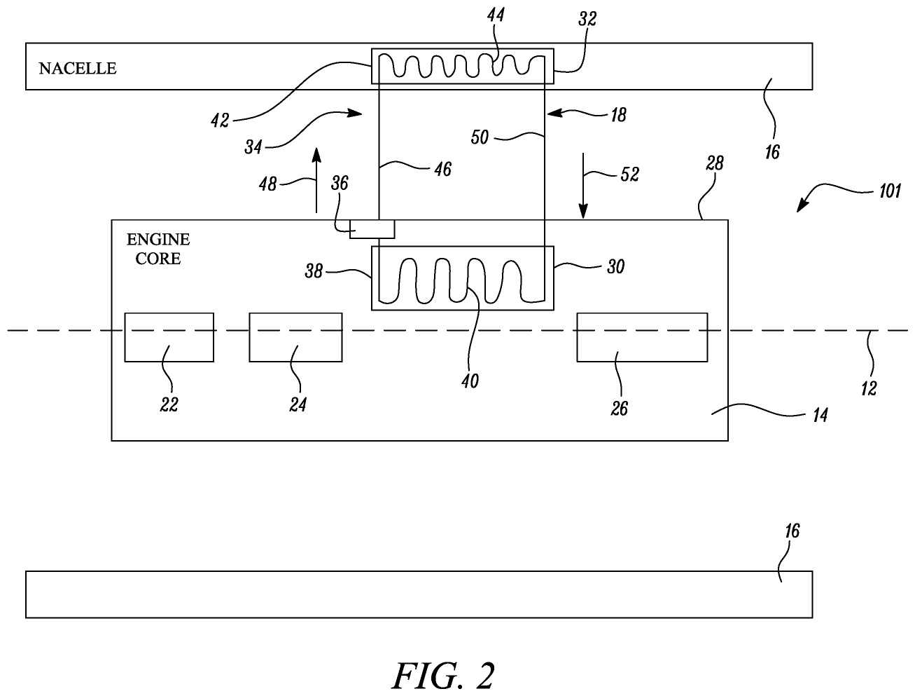

FIG. 2 illustrates a schematic diagram of apparatus for a gas turbine engine according to a second example;

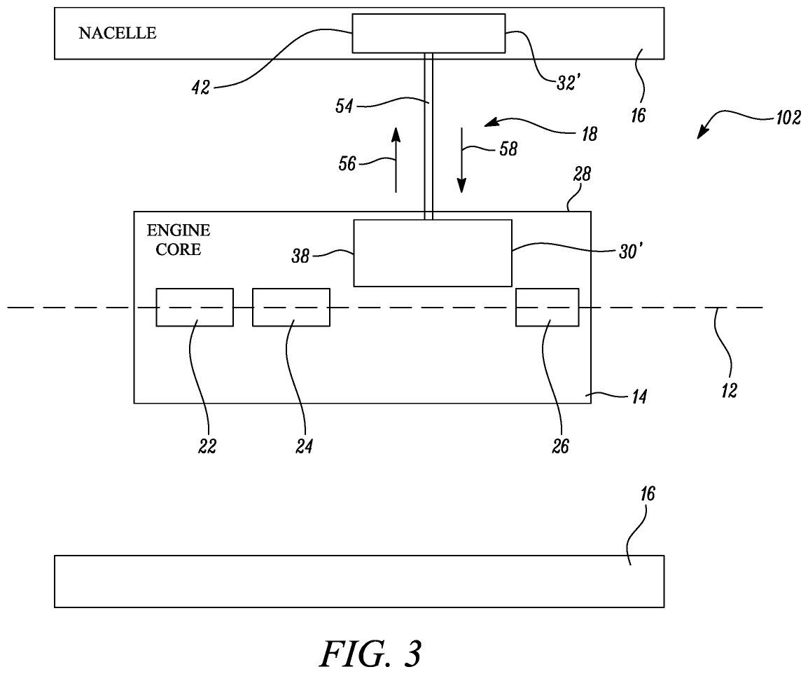

FIG. 3 illustrates a schematic diagram of apparatus for a gas turbine engine according to a third example;

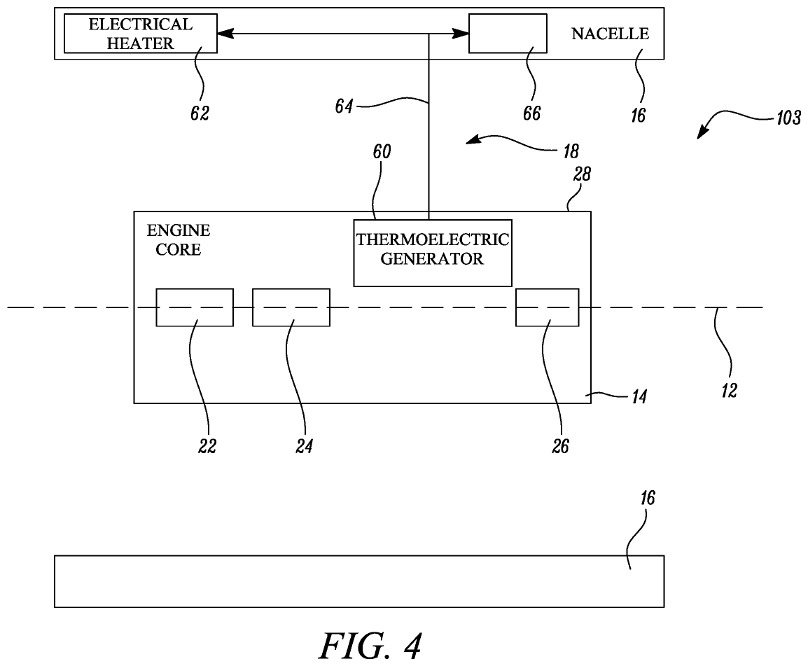

FIG. 4 illustrates a schematic diagram of apparatus for a gas turbine engine according to a fourth example;

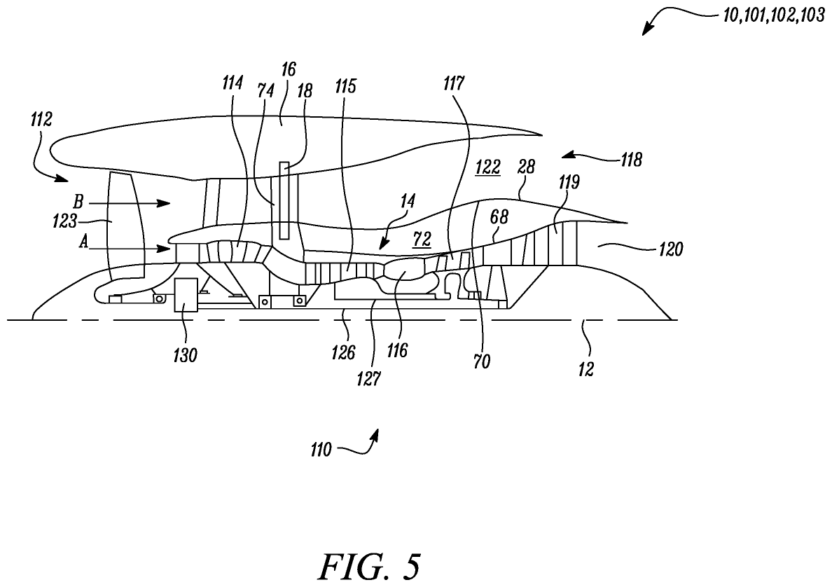

FIG. 5 illustrates a cross sectional side view of a gas turbine engine according to a first example;

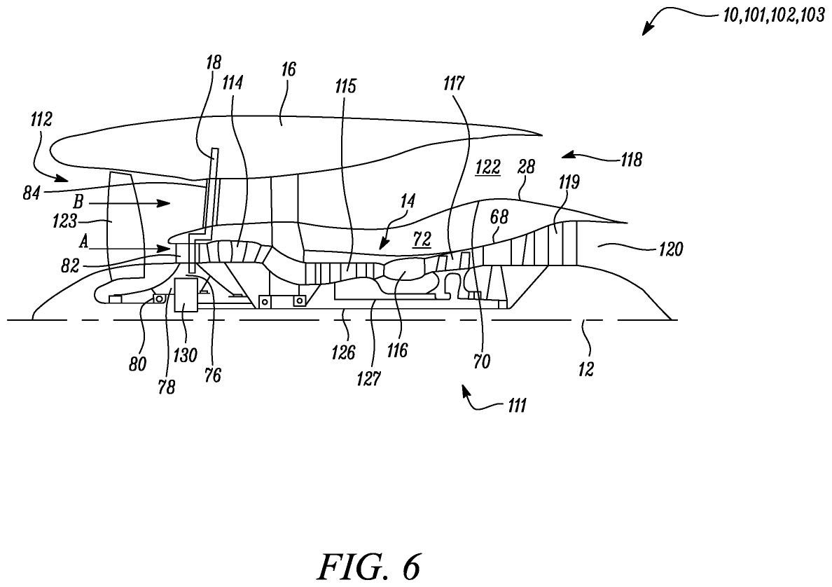

FIG. 6 illustrates a cross sectional side view of a gas turbine engine according to a second example;

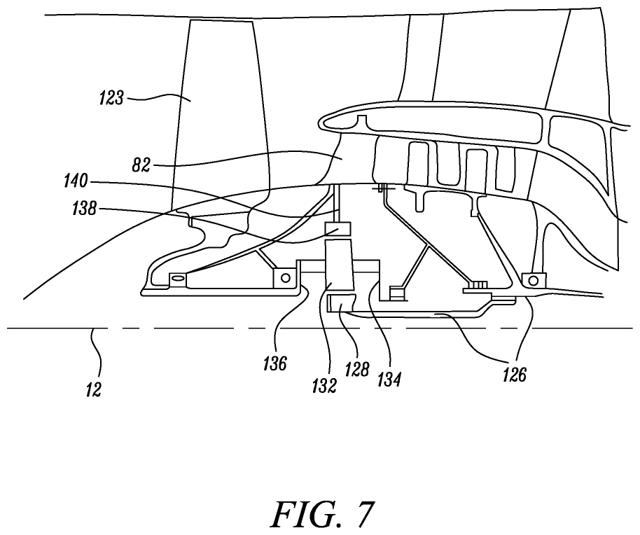

FIG. 7 illustrates a close up sectional side view of an upstream portion of the gas turbine engines illustrated in FIGS. 5 and 6; and

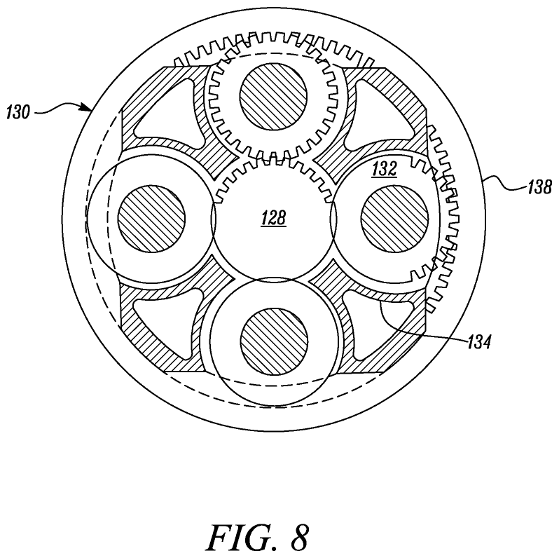

FIG. 8 illustrates a partially cut-away view of a gearbox for the gas turbine engines illustrated in FIGS. 5, 6 and 7.

### DETAILED DESCRIPTION

In the following description, the terms ‘connected’ and ‘coupled’ mean operationally connected and coupled. It should be appreciated that there may be any number of intervening components between the mentioned features, including no intervening components.

FIG. 1 illustrates a schematic diagram of apparatus 10 for a gas turbine engine according to a first example. The apparatus 10 has a longitudinal axis 12 and comprises an engine core 14, a nacelle 16, and thermal energy transfer apparatus 18. The thermal energy transfer apparatus 18 is configured to transfer thermal energy from the engine core 14 to the nacelle 16 (as indicated by arrow 20). The thermal energy transfer apparatus 18 may cause transformation of energy (for example, between thermal energy and electrical energy) or may not cause transformation of energy.

In some examples, the apparatus 10 may be a module. As used herein, the wording ‘module’ refers to an architecture, device, or system where one or more features are included at a later time and, possibly, by another manufacturer or by an end user. For example, a set of fan blades may be added to the apparatus 10 at a later time by another manufacturer or end user.

FIG. 2 illustrates a schematic diagram of apparatus 101 for a gas turbine engine according to a second example. The apparatus 101 is similar to the apparatus 10 and where the features are similar, the same reference numerals are used.

The engine core 14 includes a compressor section 22, a combustion section 24, a turbine section 26, and is housed within a casing 28. The thermal energy transfer apparatus 18 includes a first heat exchanger 30, a second heat exchanger 32, and a conduit arrangement 34. The thermal energy transfer apparatus 18 may additionally include a pump 36.

The first heat exchanger 30 is coupled to the engine core 14 and/or to the casing 28 and is configured to transfer thermal energy generated by the engine core 14 to a fluid (such as oil or other suitable material). In some examples, the first heat exchanger 30 includes a thermally conductive member 38 and one or more conduits 40.

The thermally conductive member 38 (which may also be referred to as a heat sink) is arranged to absorb thermal energy from the engine core 14 and may be connected to a part of the engine core 14 and/or to a part of the casing 28 via a plurality of fasteners (such as rivets, or bolts, or screws and so on), via welding, or via an adhesive. For example, the thermally conductive member 38 may comprise a metallic block and may comprise a plurality of fins to increase the surface area of the thermally conductive member 38.

The one or more conduits 40 extend through the thermally conductive member 38 and may comprise one or more pipes, and/or may comprise one or more bores through the thermally conductive member 38. The first heat exchanger 30 may be positioned in any section (or sections) of the engine core 14 and may overlap axially with the compressor section 22, the combustion section 24 or the turbine section 26.

The second heat exchanger 32 is coupled to the nacelle 16 and is configured to transfer thermal energy from the fluid. In some examples, the second heat exchanger 32 includes a thermally conductive member 42 and one or more conduits 44.

The thermally conductive member 42 is arranged to release thermal energy from the fluid and may be connected to the nacelle 16 via a plurality of fasteners (such as rivets, bolts, screws and so on), via welding, or via an adhesive. For example, the thermally conductive member 42 may comprise a metallic block and may comprise a plurality of fins to increase the surface area of the thermally conductive member 42. The thermally conductive member 42 may provide part of the air washed surface of the nacelle 16.

The one or more conduits 44 extend through the thermally conductive member 42 and may comprise one or more pipes, and/or may comprise one or more bores through the thermally conductive member 42. The second heat exchanger 32 may be positioned in any section of the nacelle 16. For example, the second heat exchanger 32 may be positioned at the front of the nacelle 16 (that is, the left hand side of the nacelle 16 illustrated in FIG. 2).

The conduit arrangement 34 comprises a first conduit 46 that is connected between the first heat exchanger 30 and the second heat exchanger 32 and is configured to enable the fluid to flow from the first heat exchanger 30 to the second heat exchanger 32 (as indicated by arrow 48). The conduit arrangement 34 also comprises a second conduit 50 connected between the first heat exchanger 30 and the second heat exchanger 32. The second conduit 50 is separate from the first conduit 46 (that is, the second conduit 50 is a different structure to the first conduit 46 and is spaced apart from the first conduit 46) and is configured to enable the fluid to flow from the second heat exchanger 32 to the first heat exchanger 30.

The pump 36 is configured to pump the fluid around the loop formed by the first heat exchanger 30, the second heat exchanger 32 and the conduit arrangement 34. For example, the pump 36 may be an electrically powered pump that is controllable by an engine control unit, or the pump may be mechanically driven from the engine gearbox.

It should be appreciated that the thermal energy transfer apparatus 18 may include one or more further loops of first heat exchangers 30, second heat exchangers 32 and conduit arrangements 34. The one or more further loops may be positioned in the same axial section as the loop illustrated in FIG. 2 (but at a different azimuthal position), or may be positioned at a different axial section as the loop illustrated in FIG. 2 (at the same azimuthal position, or at a different azimuthal position).

In operation, the compressor section 22, the combustion section 24, and the turbine section 26 generate thermal energy that causes the engine core 14 to be warmer than the nacelle 16. Thermal energy is transferred from the engine core 14 to the fluid at the first heat exchanger 30. The fluid flows from the first heat exchanger 30 to the second heat exchanger 32 via the first conduit 46 and thermal energy is transferred from the fluid to the nacelle 16 and/or to the environment at the second heat exchanger 32. The fluid then returns to the first heat exchanger 30 via the second conduit 50.

FIG. 3 illustrates a schematic diagram of apparatus 102 for a gas turbine engine according to a third example. The apparatus 102 is similar to the apparatus 10, 101 and where the features are similar, the same reference numerals are used.

The conduit arrangement 18 comprises one or more heat pipes 54 connected between a first heat exchanger 30′ and a second heat exchanger 32′. In operation, liquid within the heat pipe 54 contacts the thermally conductive member 38 of the first heat exchanger 30′ and turns into a vapour by absorbing thermal energy from the thermally conductive member 38. The vapour then travels along the heat pipe 54 to the thermally conductive member 42 of the second heat exchanger 32′ (as indicated by arrow 56) and condenses back into a liquid, releasing thermal energy. The liquid then returns to the thermally conductive member 38 of the first heat exchanger 30′ via capillary action (as indicated by arrow 58).

It should be appreciated that in some examples, the apparatus 102 may comprise a plurality of first heat exchangers 30′, a plurality of second heat exchangers 32′, and a plurality of heat pipes 54 connected between the plurality of first heat exchangers 30′ and the plurality of second heat exchangers 32′.

FIG. 4 illustrates a schematic diagram of apparatus 103 for a gas turbine engine according to a fourth example. The apparatus 103 is similar to the apparatus 10, 101, 102 and where the features are similar, the same reference numerals are used.

The thermal energy transfer apparatus 18 comprises a thermoelectric generator 60 and an electrical heater 62. The thermoelectric generator 60 is coupled to the engine core 14 and/or to the casing 28 and is configured to generate electrical energy from thermal energy produced by the engine core 14. In more detail, the thermoelectric generator 60 may be positioned at any location within, or on the engine core 14 and casing 28 which provides a thermal gradient across the thermoelectric generator 60 when the engine core 14 is in operation. For example, the thermoelectric generator 60 may be coupled to the casing 28 where a temperature gradient is caused by the relatively cool airflow in the bypass duct and the relatively high temperatures of the engine core 14.

The electrical heater 62 is coupled to, or part of the nacelle 16 and is configured to receive electrical energy generated by the thermoelectric generator 60 via one or more cables 64 for example. The electrical heater 62 may be positioned in any section of the nacelle 16. For example, the electrical heater 62 may be positioned at the front of the nacelle 16 (that is, the left hand side of the nacelle 16 illustrated in FIG. 4). The electrical heater 62 may transfer thermal energy to the nacelle 16 through conduction and/or convection and/or radiation and/or may transfer thermal energy to the air stream through convection and/or radiation.

In some examples, the thermal energy transfer apparatus 18 may additionally comprise an electrical component 66 that is configured to receive electrical energy generated by the thermoelectric generator 60. For example, the electrical component 66 may comprise an electrical energy storage device (such as a battery or a super capacitor) that is configured to store electrical energy generated by the thermoelectric generator 60. The electrical energy storage device 66 may be located in the nacelle 16 as illustrated in FIG. 4, or may be located within the engine core 28 (for example, within a cavity of the casing 28). In another example, the electrical component 66 may be an electrical machine within the engine core 14 that is configured to provide torque to a rotatable part of the engine core 14 (such as a shaft or a rotor).

In operation, the compressor section 22, the combustion section 24, and the turbine section 26 generate thermal energy that causes a temperature gradient across the thermoelectric generator 60. The thermoelectric generator 60 generates electrical energy that is supplied to the electrical heater 62 (and optionally, the electrical component 66) via the one or more cables 64. The electrical heater 62 converts the electrical energy to thermal energy which heats the nacelle 16.

In some examples, the block at reference numeral 62 may not be a heater and may instead be any device that can dissipate or use the electrical energy received from the thermoelectric generator 60. Furthermore, the apparatus 103 may comprise a plurality of thermoelectric generators 60, a plurality of electrical heaters 62, and a plurality of cables 64.

The apparatus 10, 101, 102, 103 may provide several advantages. First, the thermal energy transfer apparatus 18 may heat the nacelle 16 and thereby prevent the formation of ice, or reduce the growth of ice. This may enable the removal of traditional nacelle anti-ice pipework. Second, the apparatus 10, 101, 102, 103 may remove thermal energy from the engine core 14 in both high power conditions and low power conditions since the heat pipe 54 and the thermoelectric generator 60 are both passive devices and the pump 36 operates using electrical energy (which could be supplied from a source outside of the gas turbine engine). Third, the apparatus 10, 101, 102, 103 may improve turbine case cooling (TCC) effectiveness or may reduce or remove the need for a turbine case cooling system. Fourth, the apparatus 10, 101, 102, 103 may improve rotor bow at idle and sub-idle conditions. Fifth, the apparatus 10, 101, 102, 103 may increase the operable life of core mounted accessories (such as the fuel pump, oil pump, electrical machine and so on) due to the removal of thermal energy from the engine core 14.

FIG. 5 illustrates a gas turbine engine 110 comprising an apparatus 10, 101, 102, 103. The engine 110 comprises an air intake 112 and a propulsive fan 123 that generates two airflows: core airflow A; and a bypass airflow B. The gas turbine engine 110 comprises the engine core 14 that receives the core airflow A. The engine core 14 comprises, in axial flow series, a low pressure compressor 114, a high-pressure compressor 115, combustion equipment 116, a high-pressure turbine 117, a low pressure turbine 119 and a core exhaust nozzle 120. The nacelle 16 surrounds the core engine 14 and defines a bypass duct 122 and a bypass exhaust nozzle 118. The bypass airflow B flows through the bypass duct 122. The fan 123 is attached to and driven by the low pressure turbine 119 via a shaft 126 and an epicyclic gearbox 130.

In use, the core airflow A is accelerated and compressed by the low pressure compressor 114 and directed into the high pressure compressor 115 where further compression takes place. The compressed air exhausted from the high pressure compressor 115 is directed into the combustion equipment 116 where it is mixed with fuel and the mixture is combusted. The resultant hot combustion products then expand through, and thereby drive, the high pressure and low pressure turbines 117, 119 before being exhausted through the nozzle 120 to provide some propulsive thrust. The high pressure turbine 117 drives the high pressure compressor 115 by a suitable interconnecting shaft 127. The fan 123 generally provides the majority of the propulsive thrust. The epicyclic gearbox 130 is a reduction gearbox.

The casing 28 includes an inner wall 68 (such as an engine core casing) defining at least part of the core airflow path A through the gas turbine engine 110. The casing 28 also includes an outer wall 70 (such as an engine core fairing) defining an external surface of the casing 28. A first cavity 72 is defined between the inner wall 68 and the outer wall 70 of the casing 28. The thermal energy transfer apparatus 18 extends from the first cavity 72, through a vane or support 74, and into the nacelle 16. For example, where the gas turbine engine 110 includes the apparatus 101 or the apparatus 102, the first heat exchanger 30 may be positioned within the first cavity 72 of the casing 28 and the conduit arrangement 34 or the heat pipe 54 extends through the vane or support 74 to the second heat exchanger 32 in the nacelle 16. In another example where the gas turbine engine 110 includes the apparatus 103, the thermoelectric generator 60 may be positioned within the first cavity 72 of the casing 28 and the one or more cables 64 may extend through the vane or support 74 to the electrical heater 62 coupled to the nacelle 16.

FIG. 6 illustrates a cross sectional side view of another gas turbine engine 111 comprising an apparatus 10, 101, 102, 103. The gas turbine engine 111 is similar to the gas turbine engine 110 and where the features are similar, the same reference numerals are used.

The engine core 14 comprises a bearing housing 76 defining a second cavity 78 for housing a bearing 80. The thermal energy transfer apparatus 18 extends from the second cavity 78, through an engine section stator 82, through the casing 28, through a vane or support 84, and into the nacelle 16. For example, where the gas turbine engine 111 includes the apparatus 101 or the apparatus 102, the first heat exchanger 30 may be positioned within the second cavity 78 and the conduit arrangement 34 or the heat pipe 54 may extend through the engine section stator 82, the casing 28, the vane or support 84, to the second heat exchanger 32 in the nacelle 16. In another example where the gas turbine engine 111 includes the apparatus 103, the thermoelectric generator 60 may be positioned within the second cavity 78 and the one or more cables 64 may extend through the engine section stator 82, the casing 28, the vane or support 84, and to the electrical heater 62 coupled to the nacelle 16.

An exemplary arrangement for the geared fan gas turbine engine 110, 111 is shown in FIG. 7. The thermal energy transfer apparatus 18 is not illustrated in FIG. 7 to maintain the clarity of FIG. 7. The low pressure turbine 119 (see FIGS. 5 and 6) drives the shaft 126, which is coupled to a sun wheel, or sun gear, 128 of the epicyclic gear arrangement 130. Radially outwardly of the sun gear 128 and intermeshing therewith is a plurality of planet gears 132 that are coupled together by a planet carrier 134. The planet carrier 134 constrains the planet gears 132 to precess around the sun gear 128 in synchronicity whilst enabling each planet gear 132 to rotate about its own axis. The planet carrier 134 is coupled via linkages 136 to the fan 123 in order to drive its rotation about the engine axis 12. Radially outwardly of the planet gears 132 and intermeshing therewith is an annulus or ring gear 138 that is coupled, via linkages 140, to a stationary supporting structure such as the engine section stator 82.

Note that the terms “low pressure turbine” and “low pressure compressor” as used herein may be taken to mean the lowest pressure turbine stages and lowest pressure compressor stages (i.e. not including the fan 123) respectively and/or the turbine and compressor stages that are connected together by the interconnecting shaft 126 with the lowest rotational speed in the engine (i.e. not including the gearbox output shaft that drives the fan 123). In some literature, the “low pressure turbine” and “low pressure compressor” referred to herein may alternatively be known as the “intermediate pressure turbine” and “intermediate pressure compressor”. Where such alternative nomenclature is used, the fan 123 may be referred to as a first, or lowest pressure, compression stage.

The epicyclic gearbox 130 is shown by way of example in greater detail in FIG. 8. Each of the sun gear 128, planet gears 132 and ring gear 138 comprise teeth about their periphery to intermesh with the other gears. However, for clarity only exemplary portions of the teeth are illustrated in FIG. 8. There are four planet gears 132 illustrated, although it will be apparent to the skilled reader that more or fewer planet gears 132 may be provided within the scope of the claimed invention. Practical applications of a planetary epicyclic gearbox 130 generally comprise at least three planet gears 132.

The epicyclic gearbox 130 illustrated by way of example in FIGS. 7 and 8 is of the planetary type, in that the planet carrier 134 is coupled to an output shaft via linkages 136, with the ring gear 138 fixed. However, any other suitable type of epicyclic gearbox 130 may be used. By way of further example, the epicyclic gearbox 130 may be a star arrangement, in which the planet carrier 134 is held fixed, with the ring (or annulus) gear 138 allowed to rotate. In such an arrangement the fan 123 is driven by the ring gear 138. By way of further alternative example, the gearbox 130 may be a differential gearbox in which the ring gear 138 and the planet carrier 134 are both allowed to rotate.

It will be appreciated that the arrangement shown in FIGS. 7 and 8 is by way of example only, and various alternatives are within the scope of the present disclosure. Purely by way of example, any suitable arrangement may be used for locating the gearbox 130 in the engine 110, 111 and/or for connecting the gearbox 130 to the engine 110, 111. By way of further example, the connections (such as the linkages 136, 140 in the FIG. 7 example) between the gearbox 130 and other parts of the engine 110, 111 (such as the input shaft 126, the output shaft and the fixed structure) may have any desired degree of stiffness or flexibility. By way of further example, any suitable arrangement of the bearings between rotating and stationary parts of the engine (for example between the input and output shafts from the gearbox and the fixed structures, such as the gearbox casing) may be used, and the disclosure is not limited to the exemplary arrangement of FIG. 7. For example, where the gearbox 130 has a star arrangement (described above), the skilled person would readily understand that the arrangement of output and support linkages and bearing locations would typically be different to that shown by way of example in FIG. 7.

Accordingly, the present disclosure extends to a gas turbine engine having any arrangement of gearbox styles (for example star or planetary), support structures, input and output shaft arrangement, and bearing locations.

Optionally, the gearbox may drive additional and/or alternative components (e.g. the intermediate pressure compressor and/or a booster compressor).

Other gas turbine engines to which the present disclosure may be applied may have alternative configurations. For example, such engines may have an alternative number of compressors and/or turbines and/or an alternative number of interconnecting shafts. By way of further example, the gas turbine engines shown in FIGS. 5 and 6 have a split flow nozzle 118, 120 meaning that the flow through the bypass duct 122 has its own nozzle that is separate to and radially outside the core engine nozzle 120. However, this is not limiting, and any aspect of the present disclosure may also apply to engines in which the flow through the bypass duct 122 and the flow through the engine core 14 are mixed, or combined, before (or upstream of) a single nozzle, which may be referred to as a mixed flow nozzle. One or both nozzles (whether mixed or split flow) may have a fixed or variable area. In some arrangements, the gas turbine engine 110, 111 may not comprise a gearbox 130.

The geometry of the gas turbine engine 110, 111, and components thereof, is defined by a conventional axis system, comprising an axial direction (which is aligned with the rotational axis 12), a radial direction (in the bottom-to-top direction in FIGS. 5 and 6), and a circumferential direction (perpendicular to the page in the FIGS. 5 and 6 view). The axial, radial and circumferential directions are mutually perpendicular.

It will be understood that the invention is not limited to the embodiments above-described and various modifications and improvements can be made without departing from the concepts described herein. Except where mutually exclusive, any of the features may be employed separately or in combination with any other features and the disclosure extends to and includes all combinations and sub-combinations of one or more features described herein.

We claim:

1. Apparatus for a gas turbine engine, the apparatus comprising:
an engine core;
a nacelle; and
thermal energy transfer apparatus configured to transfer thermal energy from the engine core to the nacelle.

2. Apparatus as claimed in claim 1, wherein the thermal energy transfer apparatus comprises: a first heat exchanger configured to transfer thermal energy to a fluid;
a second heat exchanger configured to transfer thermal energy from the fluid;
and a conduit arrangement configured to enable the fluid to flow between the first heat exchanger and the second heat exchanger.

3. Apparatus as claimed in claim 2, wherein the conduit arrangement comprises: a first conduit connected between the first heat exchanger and the second heat exchanger and configured to enable the fluid to flow from the first heat exchanger to the second heat exchanger; and a second conduit connected between the first heat exchanger and the second heat exchanger, the second conduit being separate from the first conduit and configured to enable the fluid to flow from the second heat exchanger to the first heat exchanger.

4. Apparatus as claimed in claim 2, wherein the conduit arrangement comprises a heat pipe connected between the first heat exchanger and the second heat exchanger.

5. Apparatus as claimed in claim 2, further comprising: a casing comprising: an inner wall defining at least part of a core airflow path through the gas turbine engine; an outer wall defining an external surface of the core engine casing, a first cavity being defined between the inner wall and the outer wall of the casing, the first heat exchanger being positioned within the first cavity of the casing.

6. Apparatus as claimed in claim 2, wherein the engine core comprises a bearing housing defining a second cavity for housing a bearing, the first heat exchanger being positioned within the second cavity of the bearing housing.

7. Apparatus as claimed in claim 1, wherein the thermal energy transfer apparatus comprises: a thermoelectric generator configured to generate electrical energy from thermal energy produced by the engine core; and an electrical heater configured to receive electrical energy generated by the thermoelectric generator.

8. Apparatus as claimed in claim 7, wherein the apparatus further comprises an electrical component configured to receive electrical energy generated by the thermoelectric generator.

9. Apparatus as claimed in claim 8, wherein the electrical component comprises an electrical energy storage device configured to store electrical energy generated by the thermoelectric generator.

10. Apparatus as claimed in claim 7, further comprising: a casing comprising: an inner wall defining at least part of a core airflow path through the gas turbine engine; an outer wall defining an external surface of the casing, a first cavity being defined between the inner wall and the outer wall of the casing, the thermoelectric generator being positioned within the first cavity of the casing.

11. Apparatus as claimed in claim 7, wherein the engine core comprises a bearing housing defining a second cavity for housing a bearing, the thermoelectric generator being positioned within the second cavity of the bearing housing.

12. A gas turbine engine for an aircraft, the gas turbine engine comprising apparatus as claimed in claim 1.

13. The gas turbine engine as claimed in claim 12, wherein the engine core further comprises a turbine, a compressor, and a core shaft connecting the turbine to the compressor; a fan located upstream of the engine core, the fan comprising a plurality of fan blades; and a gearbox that receives an input from the core shaft and outputs drive to the fan so as to drive the fan at a lower rotational speed than the core shaft.

14. The gas turbine engine as claimed in claim 13, wherein: the turbine is a first turbine, the compressor is a first compressor, and the core shaft is a first core shaft; the engine core further comprises a second turbine, a second compressor, and a second core shaft connecting the second turbine to the second compressor; and the second turbine, second compressor, and second core shaft are arranged to rotate at a higher rotational speed than the first core shaft.
